(19) United States
(12) Patent Application Publication
(10) Pub. No.: US 2004/0179694 A1
(43) Pub. Date: Sep. 16, 2004

(54) Safety apparatus for audio device that mutes and controls audio output

(76) Inventor: Kenneth A. Alley, Berwick, PA (US)

Correspondence Address: LAW OFFICES OF MARK A. GARZIA, P.C., 2058 CHICHESTER AVE, BOOTHWYN, PA, 19061, US

(21) Appl. No.: 10/735,297

(22) Filed: Dec. 12, 2003

Related U.S. Application Data
(60) Provisional application No. 60/432,747, filed on Dec. 13, 2002.

(51) Int. Cl. H03G 11/00; H03G 3/20

(52) U.S. Cl. 381/55; 381/94.5; 381/58

(57) ABSTRACT

The present invention discloses a safety apparatus that monitors sounds in the ambient space and automatically adjusts and controls the sound output of an audio device to a predetermined level. Alternatively, the safety apparatus can provide a visual or tactile warning to the user depending on the type of input/sound detected.

### CROSS REFERENCE TO RELATED APPLICATIONS

The present application claims the benefits under all relevant U.S. statutes, including the benefit of priority under 35 U.S.C. §119(e), to U.S. Provisional Application No. 60/432,747 filed Dec. 13, 2002, titled HEADSET/EARPHONES WITH AUTO-MUTE SAFETY DEVICE FOR AUDIO DEVICES AND CELLULAR PHONE in the name of Kenneth A. Alley.

U.S. Provisional Application No. 60/432,747, filed Dec. 13, 2002, is hereby incorporated by reference as if fully set forth herein.

### FIELD OF THE INVENTION

The present invention relates generally to a safety apparatus for use with audio devices (including cellular telephones) and, more specifically, controlling the audio output of the audio device in a pre-determined manner (including muting, if necessary), in response to a predetermined noise level (sound spectrum) in the ambient space.

### BACKGROUND OF THE INVENTION

CD players, cellular telephones, mp3 players and a host of other audio devices are adapted with hands free headphones or headsets that incorporate speakers which provide the audio output of the various audio devices. It is becoming more common for these devices to be used during other activities (e.g., jogging, walking, driving, sleeping, etc.). The audio devices provide a source of entertainment for the user and the headphones allow the user to continue enjoying the entertainment without interfering with others in their proximity.

A typical headphone or headset will also block out the sounds happening all around the listener (referred to herein as the listener's ambient space). These sounds that occur in the ambient space may be important. While driving, the headsets or earphones not only effect the concentration of the driver but, equally important, they increase the probability that the wearer/driver will not hear and, therefore, not respond, to an emergency vehicle, horns from other vehicles, back-up beeps from trucks and from construction equipment, or other dangers or alarms.

Prior inventions have been designed so that they automatically mute the sound produced from an audio device when a loud noise is detected. For example, U.S. Pat. No. 6,002,763, to Lester et al., discloses a telephone mute ringer function. U.S. Pat. No. 6,002,763 issued Dec. 14, 1999, is hereby incorporated by reference as if fully set forth herein.

### SUMMARY OF THE INVENTION

The present invention consists of an improved safety apparatus for use with audio devices. The present invention controls the output signal to the headset or speakers of an audio device in response to ambient sound levels. If a predetermined noise level is present, the safety sensor in the headset (or attached to the audio device) will automatically control and adjust the signal. Thus, the user of the headset will hear the outside ambient noise and have the ability to respond appropriately.

The present apparatus may incorporate means to allow the user to adjust the audio output of the audio device with various sensitivity levels. Sensitivity requirements will vary from an individual jogging outside to someone driving an automobile. A switch on the device may adjust the sensitivity for different settings. For example, a person inside a house may use a higher sensitivity level than a driver since there is additional noise present when driving (from the engines of the automobiles, heater/air-conditioning fans, etc.).

The present invention consists of an electrical circuit that communicates with the audio device in order to control the output signal to the headphone, earphone, or speakers. The safety device may be incorporated directly into the audio device (including a home entertainment system), or attached to the audio device with wires or via a wireless link (e.g., microwaves, or infrared). The present apparatus may also be built directly into the headsets or output listening devices (speakers), etc.

A preferred embodiment will use existing headsets and existing audio devices. In this embodiment, the safety apparatus will have means to plug into a typical audio device and also have means for a typical headset to be plugged into the safety apparatus using various jacks currently manufactured on the respective devices. Instead of immediately muting the output of the audio device, the present safety apparatus allows the user various options, including to lower the sound level emanating from the headphones, or to provide a visual or tactile warning to the user. The safety apparatus incorporates an input means that allows the user to program various responses to ambient sounds before the sounds are encountered. The program may be altered depending on the type of audio device or where the user will be operating the audio device (behind the wheel of a car, in the home, jogging in a park, etc.).

The present safety apparatus may also incorporate LED's to show its operating status. The safety apparatus may also incorporate wireless means to communicate with the user.

The present invention may also include multiple or alternative feedback means such as a controlled vibration to alert the user of outside noise. Such a safety apparatus may have beneficial applications for the hearing impaired. In this embodiment the sensor may be worn on the individual's wrist and, if a loud noise such as a fire alarm is detected, the safety sensor may be programmed to vibrate (providing tactile means to alert the deaf individual).

The present invention may analyze any sound received in order to provide a specific notice or warning to the user. Sound intensity and frequency may be analyzed and an appropriate output response can be made by the safety apparatus. For example, if a user was deaf and was making a pot of tea on the stove, the safety apparatus can be designed and programmed to alert the deaf individual that the water in the tea pot was boiling by flashing a green LED.

The present invention does not just automatically mute the audio output upon detecting a loud ambient noise, but allows the user to predetermine and set various parameters, including the level of muting, the type and/or loudness of the sound detected that will activate a warning, and even the type of warning (visual, tactile).

### BRIEF DESCRIPTION OF THE DRAWINGS

The accompanying drawings, which are incorporated in and form a part of the specification, illustrate the embodiments of the present invention and, together with the following description, serve to explain the principles of the invention. For the purpose of illustrating the invention, there are shown in the drawings embodiments which are presently preferred, it being understood, however, that the invention is not limited to the specific instrumentality or the precise arrangement of elements or process steps disclosed.

In the drawings:

FIG. 1 is a plan view of a new safety apparatus or system, for use with a typical headset/ headphone/earphone, and a typical audio device. A headset may be connected to an output connector of the safety apparatus and an audio device is connected to an input connector of the safety apparatus.

FIG. 2 is a front plan view of another embodiment of the new safety apparatus shown in FIG. 1 which is adapted to be attached directly to a headset. (Also, this embodiment includes an optical feedback lens for visual feedback.) FIG. 3 is a front plan view of another embodiment of the safety apparatus illustrated in FIG. 1 which is adapted to attach directly onto the backside of an output earpiece/speaker. (A smart speaker with means to monitor, react and communicate with the audio device by means of monitoring the outside sound levels.) FIG. 4 is a schematic block diagram of the safety apparatus illustrated in FIG. 1 in accordance with the present invention.

### DETAILED DESCRIPTION OF THE PREFERRED EMBODIMENT

In describing a preferred embodiment of the invention, specific terminology will be selected for the sake of clarity. However, the invention is not intended to be limited to the specific terms so selected.

FIG. 1 is a perspective view of a new safety apparatus in accordance with the present invention and is indicated at 10. The safety apparatus 10 may be adapted to a typical headset (not shown) and a typical audio device (not shown). A standard headset jack 13 is plugged into the safety apparatus 10 at output terminal 15. Wire 11 connects headset jack 13 to a typical headset. A second jack 26 on the safety apparatus 10 connects a typical audio device to the safety apparatus via connection cable 23. In this illustration, the safety apparatus 10 is a separate unit and utilizes the typical connectors and jacks found on many audio systems. In other words, this particular embodiment provides means to use existing audio devices and existing headsets with no modifications.

The basic circuits and elements needed to manufacture the present safety apparatus are known in the industry. For example, U.S. Pat. No. 5,987,106 issued Nov. 16, 1999, to John S. Kitamura, discloses an Automatic Volume Control System and Method for Use in a Multimedia Computer System. U.S. Pat. No. 5,987,106 is hereby incorporated by reference as if fully set forth herein. The present safety apparatus 10, although it utilizes circuits known in the industry, incorporates features and functions that are novel to this type of apparatus.

Prior art devices do not allow the user to adjust the sensitivity of the safety apparatus to allow for different sounds and/or different loudness, pitch, etc. In the present invention, the sound level (decibels) at which the safety apparatus 10 is activated may be changed or modified by the user. For example, the range upon which a user may change the sensitivity at which the safety apparatus 10 will activate could be from 70 dBs to 125 dBs. Whereas a prior art apparatus will only activate at one specific sound level, say 115 dBs.

Also, many prior art apparatus only perform one or a very limited function. The most common function is that when a triggering event (a siren that exceeds 115 dBs) is received by the prior apparatus, it automatically mutes the sound coming from the speakers. In the present invention, the user may choose to mute the sound upon the detection of an emergency siren, may choose to only lower the sound volume upon the detection of a back-up warning from a construction truck, may provide a simple notice (three beeps) if it detects the sound of an automobile horn, etc.

Referring now to FIG. 4, a schematic diagram of the safety apparatus 10 is shown. Output terminal 15 connects the safety apparatus to the headphones or other device that produces the music to which the user is listening. A second connector 26 allows the audio device (e.g., cell phone, MP3 player, CD player, etc.) to conveniently connect to the safety apparatus 10 via wire 23.

Still referring to FIG. 4, a microphone 17 or other sound detector that picks up sounds from ambient space and converts those sound waves into electrical current is utilized. Sound detector 17 will be sensitive enough to be able to detect the desired sounds that will trigger a response from the safety apparatus 10. The sound detector 17 monitors outside or noise levels in ambient space and, depending on the safety apparatus settings, the safety apparatus 10 will communicate with the output signal of the audio device and the headset/earphones.

A pre-amplifier 90 or other first stage amplifier amplify the relevant signal corresponding to the sounds picked up by the microphone 17. A filter (not shown) may be utilized to clean or re-shape the signal corresponding to the noise picked up from the ambient space.

A comparator 92 may be used to determine the difference in voltage levels and signal a controller circuit 99 as to whether any action should be taken.

The various components (including input switches 19, comparator 92, jacks 13, 26 for connections to the headphones and audio device, respectively) are all connected to a controller circuit 99. The controller circuit 99 may include a microprocessor, a gate array, or other common logic circuits and will implement the various functions of the safety apparatus 10.

As indicated previously, the user defined parameters can be input by switches or keys 19. This data input by the user may be temporarily or permanently stored in memory 91. The controller 99 can access and retrieve the various user settings from memory 91 when a triggering event (e.g., an emergency siren) is detected.

Input keys 19 allow the user a way to adjust and change the various settings of the safety apparatus 10. For example, sensitivity levels of the microphone 17 may be made through the input keys 19. Other modifications, for example, which sounds (loudness, frequency, duration) will activate the safety apparatus 10, and what happens when the safety apparatus is activated (e.g., automatic muting of the sounds/music coming from the headphones, a visual or tactile warning, etc.) May be set or modified by the keys 19.

The sound is responsive to sounds in the audio spectrum. The sound detector 17 may typically be a speaker or similar device that converts audio into an electrical signal.

Resent button 21 on the safety apparatus 10 resets the apparatus, preferably to a base or start-up level. New values to modify the safety apparatus settings may be input by keys 19. Specifically, reset button 21 may delete all values stored in memory, and reset the controller circuit 99.

It cannot be overemphasized how prior art devices, upon sensing a triggering event (e.g. a siren) are designed to respond in one specific fashion, which is, usually, to automatically mute the output of the audio device. The present invention, allows the user to control the sounds upon which the safety device 10 will respond, and it allows multiple responses or outputs depending on the triggering event.

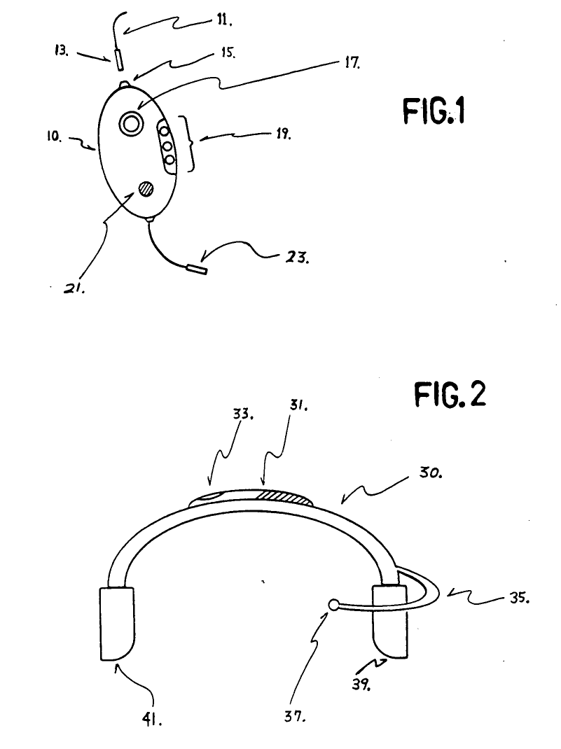

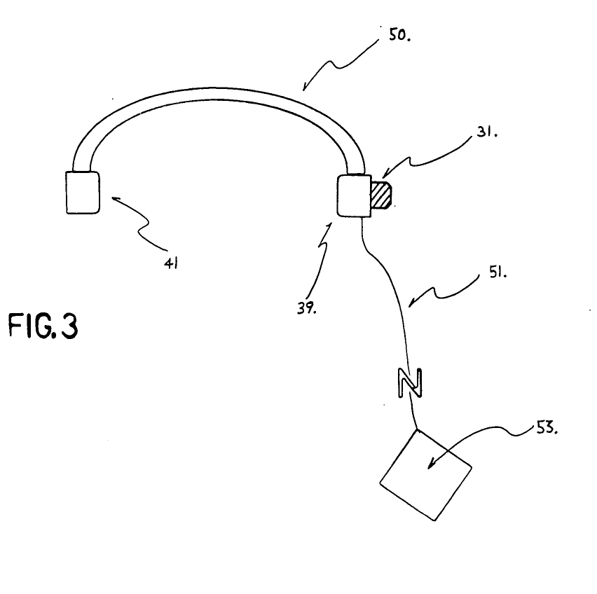

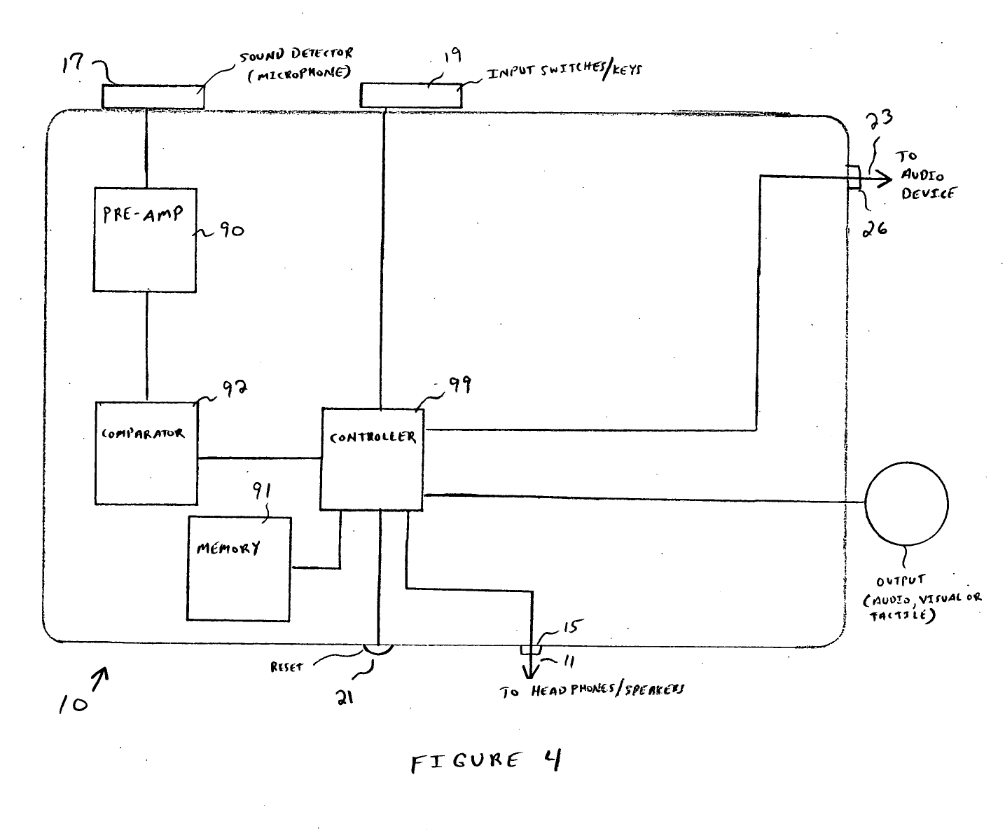

Referring now to FIG. 2, a plan view of another embodiment of the safety apparatus 31 is shown. The safety apparatus 31 is integrated directly into the headset 30. Headset 30 adapts a flexible and adjustable optical arm 35 and optical lens 37 (or any means to communicate with the user through light or color) thus providing alternative optical/visual feedback to the user.

As in the previous embodiment of FIG. 1, sound detector 33 will monitor outside or ambient noise levels and, depending on the settings of the safety apparatus 31, the safety apparatus 31 will communicate with the output signal of the audio device and the headset/earphones. The right speaker 41 and the left speaker 39 may be muted or controlled independently or together depending on the user defined settings of the safety apparatus 31 previously described.

Headset 30 includes optical feedback means that will activate upon the detection of a triggering event detected by microphone 33. The optical lens 37 may be programmed to flash at various frequencies depending on the safety apparatus 31 settings. It may also be desired to adapt a vibrator to headset 30 so that a person (especially a blind person) may receive tactile warning of a triggering noise/event.

In this embodiment, the user, upon seeing the warning light or LED, can take appropriate action (i.e., turn off the audio device, pull the car/bike to the side of the road, etc.). In this embodiment, the safety apparatus 31 does not always have to mute or lower the volume to the headphones. Of course, upon the detection of an emergency siren, the safety apparatus 31 may convey multiple actions.

#33. Sound Sensor Receiver/Detector

#35. Optical Feedback adjustment arm (alternative to muting audio player output signal)

Referring now to FIG. 3, a perspective side view of headset 50 where the safety apparatus system 31 is adapted directly onto the opposite or backside of the output speaker 39. Connection cable 51 attaches the headset and safety apparatus 31 to a typical audio device 53. (A smart speaker with means to monitor and react /communicate with the audio device by means of monitoring the outside decibel levels or sound spectrum).

An alternative embodiment of a headphone system in accordance with the present safety apparatus 31 shown in FIG. 3 and indicated by reference numeral 50.

An audio device 53 is connected to the headphone system 50. A left headphone speaker 39 and a right headphone speaker 41 are muted as described previously by the safety apparatus 31.

Connection cable 51 connects the headset/earphone to the audio device 53. Audio Device (Note: The Safety Sensor could be built directly into the audio player circuitry).

Although this invention has been described and illustrated by reference to specific embodiments, it will be apparent to those skilled in the art that various changes and modifications may be made which clearly fall within the scope of this invention. The present invention is intended to be protected broadly within the spirit and scope of the appended claims. * * * * *

I claim:

1. A safety apparatus for use with an audio device, the audio device having an output circuit for controlling a signal to a means for outputting sound, the safety apparatus comprising:
a) a detector circuit for detecting the presence of a pre-determined sound;
b) a mute circuit connected to the detector circuit and cooperative with the audio device for controlling the output circuit and hereby permitting the mute circuit to control said signal to the means for outputting sound.

2. The safety apparatus of claim 1 wherein said means for outputting sound is a head phone.

3. The safety apparatus of claim 1 wherein said means for outputting sound is a speaker.

4. The safety apparatus of claim 1 wherein said mute circuit turns off the signal to said means for outputting sound.

5. The safety apparatus of claim 1 wherein said mute circuit lowers the signal thereby reducing the sound output of said means for outputting sound.

6. The safety apparatus of claim 1 wherein said predetermined sound is an emergency (police/ambulance) siren.

7. The safety apparatus of claim 1 having input means to allow the user to modify the detector circuit for responding to different noises and sounds.

8. A portable safety apparatus for use by disabled person (e.g., hearing impaired), the safety apparatus comprising:
a detector circuit for detecting the presence of a pre-determined sound;
a notice circuit connected to said detector circuit, and usable by the disabled person to notify said disabled person of the presence of a pre-determined sound.

9. The safety apparatus of claim 8 having input means to allow the customization of the notice circuit for modifying the types of notice (mute, visual, tactile) given to the person.

10. The safety apparatus of claim 8 wherein said safety apparatus is wearable by the disabled person.

11. The safety apparatus if claim 8 wherein said safety apparatus includes a chain and a means for hanging said safety apparatus from the neck of said disabled person.

12. The safety apparatus if claim 8 wherein said safety apparatus includes a chain and a means for hanging said safety apparatus from the neck of said disabled person.

13. The safety apparatus of claim 8 wherein said notice circuit provides a tactile warning (e.g., vibration) to the disabled person.

14. The safety apparatus of claim 8 wherein said pre-determined sound is a siren.
